(19) United States
(12) Patent Application Publication
(10) Pub. No.: US 2023/0049186 A1
(43) Pub. Date: Feb. 16, 2023

(54) Optical Component, Optoelectronic Semiconductor Component and Method for Producing an Optical Component

(71) Applicant: OSRAM Opto Semiconductors GmbH, Regensburg (DE)

(72) Inventors: Jens Eberhard, Lemgo (DE); Andreas Hanisch, Regensburg (DE); Norwin von Malm, Nittendorf (DE)

(73) Assignee: OSRAM Opto Semiconductors GmbH, Regensburg (DE)

(21) Appl. No.: 17/785,747

(22) PCT Filed: Dec. 14, 2020
(86) PCT No.: PCT/EP2020/085970

§ 371 Date: Jun. 15, 2022

(30) Foreign Application Priority Data
Dec. 17, 2019 (DE) 10 2019 134 728.9

(51) Int. Cl. H01L 33/46; H01L 33/00; H01L 25/075

(52) U.S. Cl. CPC H01L 33/46; H01L 33/005; H01L 25/0753; H01L 2933/0025

(57) ABSTRACT

In an embodiment an optical component includes an optical body at least partially translucent to visible light and a coating directly arranged at the optical body, wherein the coating has a reflection coefficient of at least 0.8 for at least one wavelength range in a range from 380 nm to 1500 nm and an average thickness between 10 μm and 200 μm inclusive, wherein the coating has a polysiloxane as base material, and wherein the polysiloxane comprises —SiO_{3/2} units.

This patent application is a national phase filing under section 371 of PCT/EP2020/085970, filed Dec. 14, 2020, which claims the priority of German patent application 102019134728.9, filed Dec. 17, 2019, each of which is incorporated herein by reference in its entirety.

### TECHNICAL FIELD

An optical component is specified. Furthermore, an optoelectronic semiconductor component having such an optical component is disclosed. Finally, a method for producing such an optical component is disclosed.

### BACKGROUND

International Application No. WO 2010/098448 A1 concerns a polysiloxane-based surface coating.

In US Applicant Publication No. 2010/0249339 A1 a process of production for polysiloxanes can be found.

One problem to be solved is to specify a temperature-resistant optical component.

### SUMMARY

Embodiments provide, among other things, an optical component, an optoelectronic semiconductor component and a process of production of an optical component.

According to at least one embodiment, the optical component is provided for an optoelectronic semiconductor component. The optoelectronic semiconductor component is in particular a light-emitting diode, LED for short, or a light-emitting diode-based component. Accordingly, the optical component has geometric dimensions and optical, mechanical and thermal properties that are suitable for an optoelectronic semiconductor component, in particular for an LED.

According to at least one embodiment, the optical component comprises an optical body. The optical body is at least partially translucent to visible light. In particular, the optical body is light-transmissive in at least a partial range of the visible spectral range, for example at wavelengths above 530 nm or above 430 nm. Translucent means in particular that a transmittance of the optical body in the at least one respective spectral range is at least 75% or 90%. The optical body can be transparent or diffusely scattering.

According to at least one embodiment, the optical component comprises a coating. The coating is preferably applied directly to the optical body. That is, the coating covers the entire surface of the optical body or, preferably, only directly in places.

According to at least one embodiment, the coating is comparatively thin. That is, the coating has an average thickness of at least 20 μm or 40 μm. Alternatively or additionally, the average thickness of the coating is at most 200 μm or 100 μm. In particular, the coating has an average thickness between 10 μm and 100 μm, inclusive, or between 20 μm and 50 μm, inclusive. It is possible that the coating has a selectively adjusted thickness gradient. Preferably, however, the coating has a constant, uniform layer thickness as intended.

According to at least one embodiment, the coating has a polysiloxane as base material. The base material preferably extends contiguously and/or without selective, macroscopic inhomogeneities throughout the coating. The coating may comprise the base material, or the base material may be a matrix for another component of the coating, such as particles embedded in the base material. Such particles are preferably distributed homogeneously in the coating, i.e. without a specifically adjusted macroscopic gradient.

According to at least one embodiment, the polysiloxane forming the base material comprises —SiO_{3/2} units. That is, at least some of the base units of the polysiloxane are so-called trifunctional main elements of the at least one silicone network by which the polysiloxane is formed. Such trifunctional units are also referred to as T units. The terms —SiO_{3/2} units and T units are used synonymously herein. The polysiloxane may be a silicone resin with interlinked chains and/or with interlinked T units. If several chains are present in the polysiloxane, these chains may be linked to form a single clew.

In at least one embodiment, the optical component is for a optoelectronic semiconductor component. The optical component includes an optical body and one or more coatings. The at least one coating is directly attached to the optical body. The coating has an average thickness between 10 μm and 200 μm, inclusive, in particular between 20 μm and 100 μm, inclusive. The coating has as base material a polysiloxane, wherein the polysiloxane comprises T-units.

Furthermore, an optoelectronic semiconductor component is disclosed. The optoelectronic semiconductor component includes one or more optical components as described in connection with one or more of the above embodiments. Features of the semiconductor component are therefore also disclosed for the optical component, and vice versa.

According to at least one embodiment, the semiconductor component comprises one or more radiation-emitting optoelectronic semiconductor chips. The at least one semiconductor chip is in particular a light emitting diode chip, in short LED chip, or a laser diode chip, in short LD chip. The semiconductor component may comprise a plurality of optoelectronic semiconductor chips of identical design or may also comprise a plurality of different types of optoelectronic semiconductor chips, for example for generating radiation in different wavelength ranges. Furthermore, it is possible that the semiconductor component comprises additional semiconductor chips, which are, for example, semiconductor chips for protection against damage caused by electrostatic discharges or sensor chips, for example for temperature, brightness and/or color.

According to at least one embodiment of the semiconductor component, the at least one optical component is attached to the at least one optoelectronic semiconductor chip. The optical component may be directly attached to the semiconductor chip such that the optical component and the optoelectronic semiconductor chip are in contact or such that only a connecting means, for example an adhesive, is located between the optical component and the optoelectronic semiconductor chip.

The optical component and the optoelectronic semiconductor chip may be mounted close to each other, such that a distance between the optical component and the optoelectronic semiconductor chip is preferably at most 100 μm or 20 μm or 5 μm. In particular, a distance between the optical component and the optoelectronic semiconductor chip is smaller than an average thickness of the optical component and/or the coating.

For example, the optical component is arranged exclusively on a main surface of the semiconductor chip facing the optical component. The main surface forms in particular an outer surface of the semiconductor chip extending parallel to the main extension plane of the semiconductor chip. Side surfaces of the semiconductor chip which extend, for example, transversely or perpendicularly to the main surface are preferably free of the optical component.

According to at least one embodiment, the optical component is designed such that radiation generated by the semiconductor chip during operation is at least partially emitted out of the semiconductor component through the optical component. In particular, no or no significant portion of radiation generated by the semiconductor chip leaves the optoelectronic semiconductor component without having passed through the optical component, in particular without having passed through the optical body.

If several optoelectronic semiconductor chips are present in the semiconductor component, there can be a one-to-one assignment between the optoelectronic semiconductor chips and the optical components. Alternatively, it is possible that a single optical component is assigned to several optoelectronic semiconductor chips or to all semiconductor chips taken together. Accordingly, groupings of several optoelectronic semiconductor chips can each be provided with their own optical component so that, for example, at least two or at least four of the optoelectronic semiconductor chips and/or at most 25 or at most 16 or at most nine of the optoelectronic semiconductor chips are present per optical component.

In at least one embodiment, the semiconductor optoelectronic device comprises one or more optical components and one or more radiation-emitting optoelectronic semiconductor chips. The at least one optical component is attached to the at least one semiconductor optoelectronic chip. The optical component is configured such that radiation generated by the semiconductor chip during operation is at least partially emitted out of the semiconductor component through the optical component.

Furthermore, a method for producing an optical component for an optoelectronic semiconductor component is disclosed. Features of the method are therefore also disclosed for the optical component as well as for the optoelectronic semiconductor component and vice versa.

According to at least one embodiment, the method comprises the step of providing a plurality of optical bodies. The optical bodies may be made from a common starting material or from a common starting layer. Preferably, the optical bodies are provided spaced apart from each other, in particular in a common plane, especially on a common carrier, such as a stretchable carrier foil.

According to at least one embodiment, the method comprises the step of applying a liquid coating material to the optical bodies, in particular directly to the optical bodies. The coating material is liquid at room temperature. A viscosity of the coating material can be adjusted by a temperature during processing. The coating material can be applied, for example, by spraying or printing.

The term “liquid” includes both highly fluid materials, which have a viscosity in the range of silicone oils or of water, and viscous coating materials, which have a viscosity in the range of honey. For example, the viscosity of the coating material during application is at least 0.3 mPa·s or at least 0.6 mPa·s or at least 5 mPa·s. Alternatively or additionally, the viscosity during application is at most 100 Pa·s or 10 Pa·s or 1 Pa·s or 0.1 Pa·s.

According to at least one embodiment, the method comprises the step of solidifying the coating material to form the coating. In particular, solidifying comprises hydrolysis and/or drying, i.e., evaporation of a solvent. It is possible that the solidifying may be performed in multiple steps. For example, a first pre-solidification step to increase a viscosity of the coating material may be performed prior to application to the optical body, but the main solidification is performed after application to the at least one optical body. This main solidification may be performed in multiple steps and may include different curing steps, for example at different temperatures and/or atmospheric conditions. The solidifying is preferably thermally induced, but can also be based on irradiation.

According to at least one embodiment, the method comprises the step of separating through the coating to the optical components. The separating comprises, for example, a cutting, a sawing, a radiation treatment, such as a laser cutting, or also a breaking. Preferably, the optical bodies are not affected by this separation, so that separation lines can be exclusively adjacent to the optical bodies.

In at least one embodiment, the method is for producing an optical component for a optoelectronic semiconductor component and comprises the following steps, preferably in the order indicated:

A) providing a plurality of optical bodies,

C) applying a liquid coating material directly to the optical bodies,

D) solidifying the coating material into a coating, and

E) separating through the coating to the optical components,

wherein the finished coating has an average thickness between 10 μm and 200 μm, inclusive, and comprises as base material a polysiloxane comprising T-units.

In optoelectronic components of high performance classes with a reflector geometry, brittleness of a conventional white reflector material is often observed after a short time in operation, the reflector material usually being formed from a silicone material with highly refractive fillers such as titanium dioxide. After further stress, such components also show visible cracks and become visually conspicuous, so that a shift in a light color location can also occur, and thus become unusable for corresponding applications. This phenomenon occurs in particular in the area around optical elements, for example on, in particular, ceramic conversion elements or on elements for light bundling.

This problem stems in particular from the fact that silicone-based materials are used for reflectors, which are applied in high layer thicknesses as potting. Such materials are prone to thermally induced brittleness, whereas many thermally more stable materials are not directly suitable for LED manufacturing applications, since such more temperature-stable materials can only be processed in thin layers to handle the intrinsically higher brittleness and the presence of other crosslinking mechanisms. Therefore, a simple substitution of the softer, thicker depositable silicone-based materials with more temperature-stable polysiloxanes richer in T-units is not readily possible in terms of process technology.

Polysiloxanes with a high proportion of T-units are thermally more stable than the silicone-based softer materials currently commonly used due to the nature and number of chemical linkages. However, the use of T-rich polysiloxanes has an impact on processing methods.

With the method described here, process separation is possible, i.e. first a dedicated, lateral coating of an optical body can be carried out so that a T-rich polysiloxane material is applied as a thin layer, for example, to all side surfaces of an optical body, with embedding in a potting compound, in particular of a softer silicone, optionally being carried out later. This allows the problems otherwise associated with the use of T-rich polysiloxanes in LED technology to be handled.

Subsequent processing of corresponding optical components including coating can be carried out using established methods and materials. Corresponding components are characterized by improved thermal stability in operation, since interfaces of the optical component are formed by the thermally more stable T-rich polysiloxane, but thicker layers with the T-rich polysiloxane are not required.

In addition to the choice of a T-rich polysiloxane, it is also possible to use highly refractive fillers in the coating, in particular to obtain a white reflective coating which, depending on the degree of filling and the thickness of the layer, can have a reflectivity of more than 90% on at least one surface section of the lateral coating for light in the wavelength range from 380 nm to 780 nm, in particular in the range from 440 nm to 460 nm.

In addition to improving the thermal stability of such optoelectronic semiconductor components, the separation of the process into the production of the coating and the production of the encapsulant also allows more degrees of freedom for the reflective encapsulant applied second, since this no longer needs to be selected exclusively with regard to thermal stability and reflectivity.

Degrees of freedom for the subsequently applied encapsulant or cladding resulting from the method described herein are, in particular:
Mechanically, a selection can be made primarily based on suitability with respect to the separation method for obtaining discrete LED components by physical separation processes such as sawing, waterjet cutting or laser cutting.
From a process engineering point of view, a selection can be made according to process suitability and process effort in order to increase a throughput and/or manufacturing stability, for example by using very low-viscosity potting compounds and/or by using fast-curing potting compounds.
With regard to optical aspects, a reduction of a filling level of highly refractive particles or pigments in the encapsulant or coating can be made, since the main part of the reflectivity can already be ensured by the coating on the optical body. If necessary, there can be a complete elimination of highly refractive fillers to produce a white impression of the component, possibly combined with replacement by fillers that take into account separability or customer requirements. Thus, other colors of the cladding can be considered, for example, for applications in flashlights for mobile devices such as smartphones.

For example, spraying processes are possible for applying the coating material to discrete optical components, if necessary with a mask and/or a protective film for the desired optical exit surface. The optical components are preferably located with a small lateral distance on a temporary carrier. After the spraying process, the coating material is cured to form the coating. Subsequently, the optical components can be processed, for example by pick-and-place.

According to at least one embodiment, the method comprises a step B), which is preferably performed between the steps A) and C). In step B), a temporary mask is applied to the top faces of the optical bodies. Here, rear sides of the optical bodies in step A) are preferably applied to a carrier and the top faces are opposite the rear sides. The temporary mask is, for example, a hard mask, in particular made of a metal such as stainless steel, or a soft mask, for example made of a film or photoresist.

According to at least one embodiment, the mask used in step B) is removed, specifically completely removed, after step C), in particular before step E). That is, the mask is no longer present in the finished optical components and/or in the finished semiconductor components. Likewise, the carrier used in step A) can be partially or, preferably, completely removed.

According to at least one embodiment, only side surfaces of the optical bodies are provided with the coating material and thus with the coating. That is, the top faces and rear sides of the optical bodies can be completely or partially free of the coating and the coating material.

According to at least one embodiment, the optics bodies taper in the direction toward the top face. That is, when applied to a semiconductor chip, the optical bodies become narrower in the direction away from the semiconductor chip. This makes it possible to achieve light concentration or light bundling.

According to at least one embodiment, the finished coating has a transmission coefficient for visible light of at most 0.2 or 0.1 or 0.05 or 0.02. That is, the finished coating is opaque to light. Alternatively or additionally, the transmission coefficient of the coating for visible light is at least 0.01 or 0.05 or 0.1. That is, the coating may be specifically designed to be translucent for visible light.

According to at least one embodiment, the finished visible light coating has a reflection coefficient of at least 0.7 or 0.8 or 0.9 or 0.95 or 0.98. In this regard, the coating preferably appears white to an observer. That is, the coating may be diffusely highly reflective.

According to at least one embodiment, the coating material and thus the finished coating comprises particles such as scattering particles, for example oxide particles, in particular metal oxide particles, as scattering centers for different wavelength ranges. The particles are embedded in the base material. Particularly preferably, the particles have a greater refractive index than the base material. In particular, the refractive index of the particles exceeds the refractive index of the base material by at least 0.3 or 0.5 or 1.0. This applies in particular at a temperature of 300 K and at a wavelength of 589 nm. For example, the particles are scattering particles of titanium dioxide, of zirconium dioxide, of zinc oxide or of BaSO₄.

According to at least one embodiment, an average diameter of the particles is at least 0.15 μm or 0.19 μm or 0.3 μm. Alternatively or additionally, the average diameter of the particles is at most 1 μm or 0.45 μm or 0.3 μm. In particular, the particles have an average diameter between 0.15 μm and 0.5 μm, inclusive. The diameter values mentioned are in particular D₅₀ values.

According to at least one embodiment, a weight fraction of the particles in the coating material is at least 5% or 20% or 40%. Alternatively or additionally, this weight fraction in the coating material, i.e. in the formulation, is at most 80% or 70% or 50%. For example, the weight fraction of particles in the formulation is between 40% and 70%, inclusive.

It is possible that the particles are made of the respective oxide material and do not have a dedicated coating to improve coupling to the base material. Alternatively, a coating is present on the scattering particles to improve their embedding in the base material.

According to at least one embodiment, the optical body is a luminescent body. That is, the optical body is configured to partially or completely convert a short-wave radiation incident on the optical body or a short-wave radiation passing through the optical body into a longer-wave radiation. In particular, ultraviolet radiation is converted into visible light or blue light is partially or completely converted into green, yellow, orange and/or red light. Thus, in combination with a blue emitting LED chip, a white light source can be formed by the optical body.

It is possible for the optical body to be both a luminescent body and a tapered body for focusing light, or for the optical body to comprise both a luminescent body and a tapered body.

According to at least one embodiment, the optical body comprises a ceramic body or the optical body is a ceramic body. Preferably, the ceramic body comprises one or more phosphors or consists of one or more phosphors.

According to at least one embodiment, the method comprises a step F), which preferably follows the step D). In step F), radiation-emitting optoelectronic semiconductor chips are attached to the optical bodies, which are preferably already coated. Step F) can precede or follow step E).

According to at least one embodiment, the method comprises a step G) following step D). In step G), a cladding is created, also referred to as a potting body. The encapsulation is preferably applied directly to the coating.

According to at least one embodiment, the finished cladding has at least the thickness of the finished coating or an average layer thickness greater than the finished coating by at least a factor or 1.5 or 2 or 3. In other words, unlike the coating, the cladding is an effectively three-dimensional material, also referred to as a bulk material.

According to at least one embodiment, the cladding has a further polysiloxane as a further base material. The further polysiloxane of the cladding is preferably softer than the polysiloxane of the coating. In particular, the further polysiloxane of the cladding is free or substantially free of T units. A proportion of T units in the further polysiloxane of the cladding is in particular lower by at least a factor of 5 or 10 or 100 than a proportion of T units in the polysiloxane of the coating.

The cladding can have particles such as scattering particles, as also present in the coating. Preferably, however, a concentration of particles in the cladding is lower than in the coating. Alternatively, the cladding may be free of optically effective admixtures, in particular free of particles such as scattering particles and/or oxide particles.

The cladding is arranged, for example, only on side surfaces of the optical component. The top face of the optical body and/or a top face of the optical component is preferably free of the cladding.

According to at least one embodiment, the optical body has a mean lateral extent, for example an average diameter or an average edge length, of at least 0.2 mm or 0.5 mm or 1 mm, as viewed from above the top face. Alternatively or additionally, the average lateral extent is at most 5 mm or 3 mm or 2 mm or 1.5 mm.

According to at least one embodiment, an average thickness of the finished optical bodies is at least 30 μm or 50 μm or 120 μm. Alternatively or additionally, this average thickness is at most 2 mm or 1 mm or 0.4 mm.

According to at least one embodiment, the finished coating is thinner than the dedicated optical body. Preferably, the finished coating is also thinner than the optionally present cladding.

According to at least one embodiment, a proportion of T units and —SiO_{4/2} units taken together and based on all base units of the polysiloxane of the finished coating is at least 70% or 80% or 90% or 95%. —SiO_{4/2} units are also referred to as quadrifunctional units or Q units for short. This means that the polysiloxane of the finished coating is largely formed by T units together with Q units.

According to at least one embodiment, a proportion of the T units in the finished coating exceeds a proportion of the Q units, for example by at least a factor of 2 or 5 or 10. That is, there are significantly more T units than Q units.

According to at least one embodiment, at least 70% of the base units of the polysiloxane of the finished coating are T units. Alternatively or additionally, this proportion is at most 90% or 80%.

According to at least one embodiment, organic residues on the T units are predominantly, i.e. at least 50% or 70% or 90%, formed by aryl groups such as phenyl groups and/or by alkyl groups such as methyl groups. That is, the polysiloxane may be a phenylpolysiloxane or a methylpolysiloxane or a mixture thereof.

According to at least one embodiment, in step D), a loss in mass of the coating material, based on a hydrolyzable volatile organic content, is at least 10% and/or at least 35%.

According to at least one embodiment, the solidifying includes a final curing at a temperature of at least 150° C. and/or at most 250° C., in particular at temperatures of at least 170° C. and/or of at most 220° C. For example, a duration of the final curing is at least one hour or two hours and/or at most 48 hours or 24 hours or 16 hours. In particular, the required temperatures and curing times can be further influenced by using suitable catalyst systems.

### BRIEF DESCRIPTION OF THE DRAWINGS

In the following, an optical component described herein, an optoelectronic semiconductor component described herein and a method described herein are explained in more detail with reference to the drawing on the basis of exemplary embodiments. Identical reference signs indicate identical elements in the individual figures. However, no references to scale are shown, rather individual elements may be shown exaggeratedly large for better understanding.

It shows:

FIGS. 1, 3, 5, 7, 8, 9, and 10 schematic cross-sectional views of an exemplary embodiment of a method for producing optoelectronic semiconductor components;

FIGS. 2, 4 and 6 schematic top views of the method steps of FIGS. 1, 3 and 5;

FIGS. 11, 13 and 15 schematic sectional views of method steps of an exemplary embodiment of a further method;

FIGS. 12, 14 and 16 schematic top views of the method steps of FIGS. 11, 13 and 15;

FIG. 17 a schematic structural formula for an example of a base material of a coating ; and

FIG. 18 a schematic representation of an internal structure of an example.

### DETAILED DESCRIPTION OF ILLUSTRATIVE EMBODIMENTS

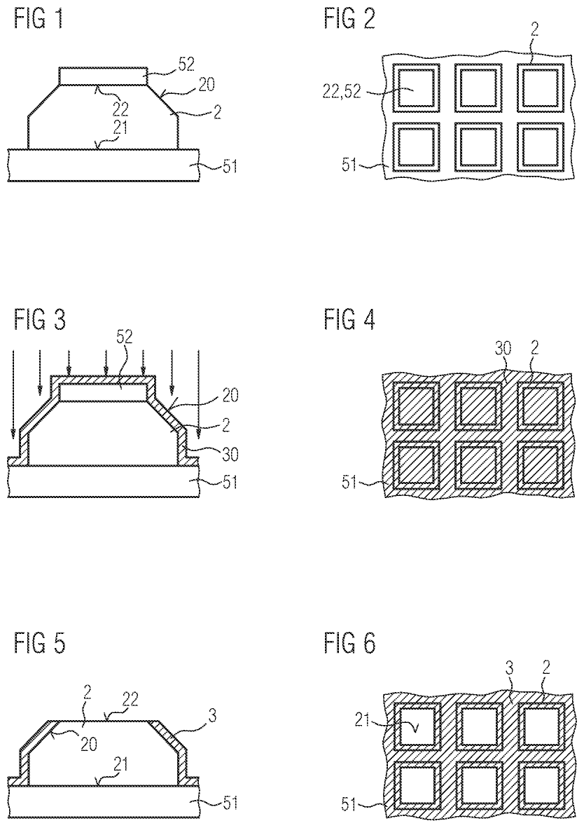

FIGS. 1 to 10 show an exemplary embodiment of a process of production for optical components 23 and for optoelectronic semiconductor components 1. In the method step of FIGS. 1 and 2, a plurality of optical bodies 2 are provided. The optical bodies 2 are located with rear sides 21 on a temporary carrier 51, and top faces 22 of the optical bodies 2 face away from the carrier 51.

For example, the optical body 2, which is transparent in particular, tapers in the direction away from the carrier 51. That is, side surfaces 20 of the optical body 2, as seen in cross section, approach each other in the direction away from the carrier 51. For example, each side surface 20, as seen in cross-section, has one or more sections that merge into one another with a kink. For example, viewed in cross-section, the optical body 2 is formed from a rectangle followed by a symmetrical trapezoid.

Seen in top view, the optical bodies 2 are, for example, square or rectangular in shape and are preferably arranged in a regular grid on the carrier 51.

Preferably, the top faces 22 of the optical bodies 2 are covered by a temporary mask 52. This means that only the side surfaces 20 are exposed. The mask 52 is formed, for example, by a photoresist or also by a hard mask, for example of stainless steel.

In the method step of FIGS. 3 and 4, it is shown that a coating material 30 is applied over the entire surface. The coating material 30 is sprayed on, for example. Preferably, the coating material 30 is deposited with a uniform thickness in particular on the side surfaces 20 and optionally also on the mask 52 and on the carrier 51 in areas between the optical bodies 2. The coating 30 is applied in a liquid state.

In the method step of FIGS. 5 and 6, it can be seen that the temporary mask 52 has been removed. This exposes the top faces 22. Solidifying of the coating material 30 results in a coating 3 that covers the side surfaces 20 with a uniform thickness all around. Solidifying can be performed in multiple steps and is preferably performed after removal, or alternatively before removal of the mask 52.

Examples of the formulation of the coating material 30 are the materials KR-220L, KR-500, KR-213, KR-510, X-40-9227, KR-9218, KR-401N, X-40-2756 or X-40-2667A from the manufacturer Shin-Etsu. Furthermore, the materials Silres SY231 or Silres IC368 from the manufacturer Wacker or silicophene types from the manufacturer Evonik, for example AC1000, can be used as coating material 30. With regard to the coating material 30, reference is also made to the publication US 2012/0058333 A1. The disclosure content of this publication, in particular paragraphs 29, 30, 31, 35, 36, 43, 50, 64 and 65 and claim 1, is incorporated by reference. Particles, such as reflective particles, are preferably added to the coating material 30 in each case. The foregoing applies in like manner to all other exemplary embodiments.

Preferably, the processing of the coating material 30 into the coating 3 is carried out as intended for the exemplary mentioned materials. In particular, solidifying the coating material 30 into the coating 3 comprises a temperature treatment, for example at about 200° for about 10 hours. In particular, the solidification of the coating material 30 is based on hydrolysis.

As is also possible in all other exemplary embodiments, the coating 3 has a glass-like consistency after complete solidification and is thus comparatively brittle. However, since the coating 3 has only a small thickness, preferably about 50 μm, negative influences of the brittleness of the coating 3 can be reduced.

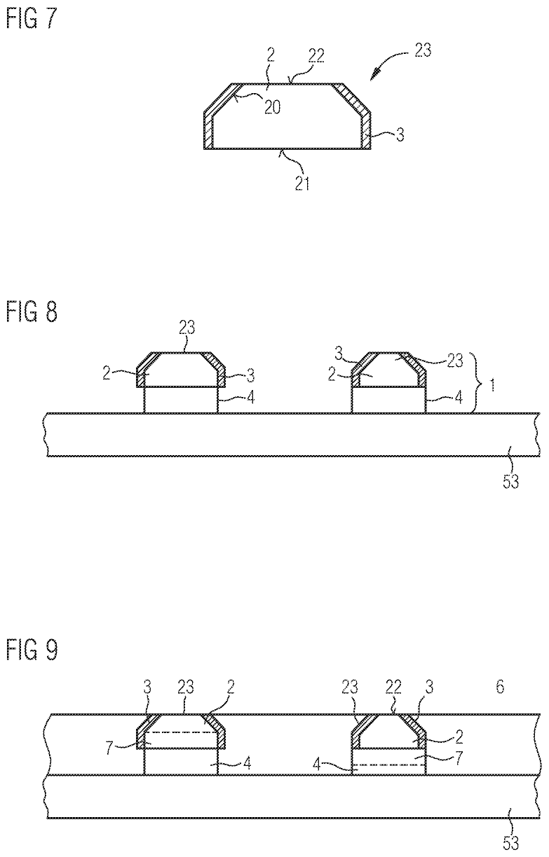

In the method step of FIG. 7, a single resulting optical component 23 comprising the optical body 2 and the coating 3 is shown. The rear side 21 as well as the top face 22 are free of the preferably reflective, white coating 3.

As in all other embodiments, it is possible that the optical body 2 specifically intended for light concentration is formed of a glass or also of another light-transmitting material such as sapphire or silicon carbide. It is also possible that the optical body 2 contains a phosphor.

In the step of FIG. 8, it is shown that the optical components 23 are applied to optoelectronic semiconductor chips 4, in particular to LED chips. This is optionally done on a further carrier 53, on which the optoelectronic semiconductor chips 4 can be mounted in a regular grid.

It is shown, see FIG. 8, left half, that the coating 3 projects laterally beyond the associated semiconductor chip 4 so that the optical body 2 is flush with the semiconductor chip 4 in the lateral direction. That is, a top face of the semiconductor chip 4 facing away from the further carrier 53 can be completely or substantially completely covered by the optical body 2.

Side surfaces of the semiconductor chip 4 that run transversely to its top face are preferably free of the optical body 2 and/or the coating 3.

In contrast, it can be seen in FIG. 8, right side, that the optical component 23 is overall flush or approximately flush with the semiconductor chip 4 in the lateral direction. That is, a top face of the semiconductor chip 4 facing away from the further carrier 53 is covered by the optical body 2 together with the coating 3.

Corresponding configurations, as shown in FIG. 8, can be present in the same way in all other exemplary embodiments.

In the optional method step of FIG. 9, it can be seen that an cladding 6 is created around the semiconductor chips 4 and around the optical components 23. The cladding 6 can be flush with the top faces 22 in the direction away from the further carrier 53. The cladding 6 is preferably a comparatively thickly applied potting compound and is in particular made of a relatively soft, further polysiloxane.

Also illustrated in FIG. 9, see the left side, is that the optical component 23 may include a luminescent body 7 in addition to the optical body 2. The luminescent body 7 comprises one or more phosphors, which may be embedded in a matrix material, for example a glass or ceramic or a third polysiloxane, or the luminescent body 7 may consist of one or more phosphors. Preferably, both the luminescent body 7 and the optical body 2 are completely coated on the side with the coating 3.

In contrast, it can be seen in FIG. 9, right half, that the separate luminescent body 7 is located between the semiconductor chip 4 and the optical component 23.

In particular, the top face 22 is free of the cladding 6. For example, the cladding 6 is arranged exclusively on a side of the coating 3 facing away from the optical body 2 and on side surfaces of the semiconductor chip 4.

These two configurations, as shown in FIG. 9, can be used in the same way in all other exemplary embodiments.

The semiconductor chip 4, the optional luminescent body 7 and the optical component 23 are bonded to one another, for example, in particular by means of a silicone adhesive, not shown. Electrical contacts of the semiconductor chips 4, not shown, are preferably each facing the further carrier 53 and thus facing away from the optical component 23. Alternatively, it is possible, not shown, for the optical component 23 and optionally the luminescent body 7 to have recesses to enable electrical contacting of the semiconductor chip 4.

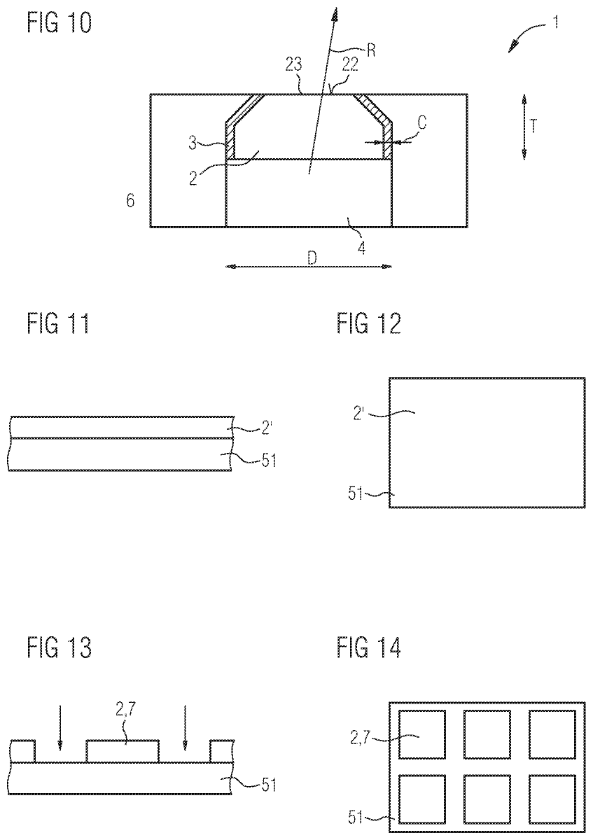

FIG. 10 shows the finished optoelectronic semiconductor component 1, which is obtained by separating the configuration of FIG. 9. Seen in cross-section, the semiconductor component 1 may be cuboidal.

As in all other exemplary embodiments, the coating 3 preferably has an average thickness C of approximately 50 μm. An average thickness T of the optical bodies 2 and the optical components 23 is, for example, in the range of 0.2 mm to 0.5 mm. A lateral extension D of the semiconductor chip 4 and thus also of the optical body 2 and the optical component 23 is approximately 1 mm. The optionally present cladding 6 is significantly thicker than the coating 3 and, unlike the coating 3, can be understood as a bulk material.

Furthermore, it can be seen from FIG. 10 that radiation R generated during operation of the semiconductor chip 4 can only leave the semiconductor component 1 through the optical component 23. It is possible that the further carrier 53 has been removed from the semiconductor chips 4 and the cladding 6. Alternatively, the further carrier 53 may remain in separated form on the semiconductor chip 4 and on the optional cladding 6, other than as illustrated in FIG. 10.

In summary, in the method according to FIGS. 1 to 10, the future optical components 23 are first produced using a layering process or a surface process, for example by means of spraying, doctor blading, screen printing or slot coating. Subsequently, the coating is applied in particular directly to the optical body 2 and optionally also to the temporary carrier 51, followed by a separation into discrete optical components 23. After this step, there is preferably an expansion of the temporary carrier material 51, which is for example a film, in order to achieve the necessary spacing, in particular a double target layer thickness of the optional cladding 6, between the optical components. However, a separate pick-and-place process is also conceivable.

In the method of FIGS. 11 to 16, an initial layer 2′ is applied to the carrier 51 for the optical bodies 2, see FIGS. 11 and 12.

Subsequently, see FIGS. 13 and 14, the initial layer 2′ is patterned to form the optical bodies 2.

In this case, the optical bodies 2 are preferably fluorescent bodies 7. Deviating from the illustration of FIG. 13, it is not mandatory that the optical bodies 2 are rectangular or approximately rectangular when viewed in cross-section. Geometries, as shown for example in connection with FIGS. 1 to 10, can also be used for the optical bodies 2.

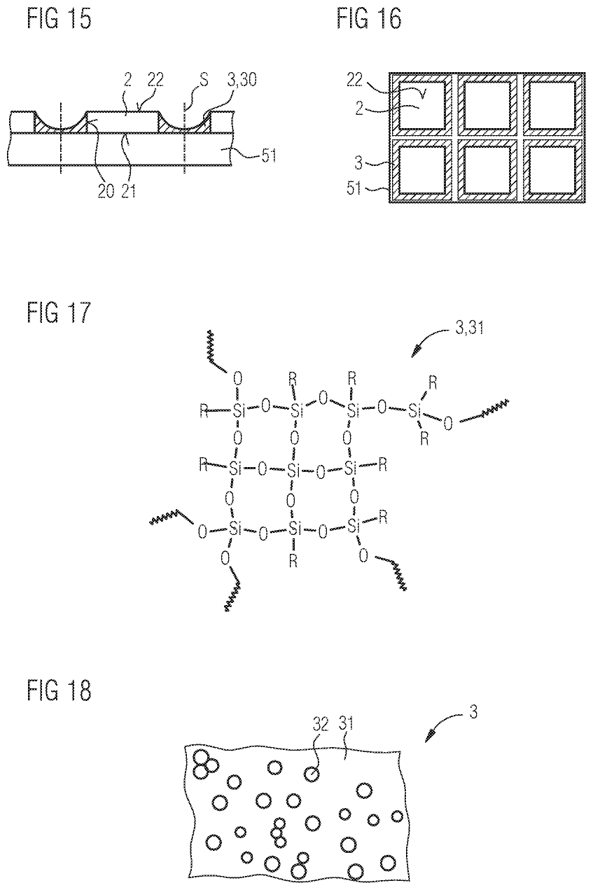

FIGS. 15 and 16 show that the coating material 30 for the coating 3 is applied only between the optical bodies 2.

Via capillary forces and/or surface properties, it is possible that the coating 3 between the optical bodies 2 has a paraboloid top face when viewed in cross-section. Separation lines S run between adjacent optical bodies 3 in the area of the coating 3 for a subsequent separation, which is carried out by means of laser radiation, for example.

The methods steps of FIGS. 7, 8, 9 and/or 10 can follow the method of FIGS. 11 to 16 in a correspondingly adapted manner.

In the method of FIGS. 11 to 16 in particular, the coating material is filled into the spaces formed between the optical bodies 2 to produce the lateral coating, for example by means of jetting or needle dispensing, if necessary using capillary force. The thin layer thus formed, which may have a groove-like shape, is cured, separated and the processed optical components 23 can be further processed accordingly, for example by pick-and-place methods. Application of the coating material 30 is also possible by means of a screen printing process in connection with FIGS. 11 to 16, if necessary with suitable masking by means of a screen and/or by means of a protective film for the light exit surfaces of the optical bodies 2, instead of by means of a dosing process.

The corresponding method steps for applying and solidifying the coating material, as illustrated in FIGS. 3 to 6 or 13 to 16, may be repeated or combined until the desired layer thickness for the coating 3 is achieved. That is, as in all other exemplary embodiments, the coating 3 may be composed of a plurality of sub-layers, each of which is produced by applying a thinner sub-layer of the coating material 30.

Optionally, a plasma step is performed between the application of each of the partial layers in order to improve adhesion to the next partial layer to be applied. Such a plasma step can also be carried out before generating the cladding 6, in order to ensure improved adhesion of the cladding 6 to the coating 3. Such plasma steps are possible in all exemplary embodiments.

In FIG. 17, schematically an exemplary structural formula of the finished coating 3 is shown, whereby optionally additionally present particles are not drawn. It can be seen from FIG. 17 that the polysiloxane is predominantly composed of T units, so that there are usually three oxygen atoms attached to the silicon atoms. There may also be some Q units, in which four oxygen atoms are attached to each silicon atom. In addition, so-called D units, i.e. —SiO_{2/2} units, can be present, in which two oxygen atoms are assigned to one silicon atom.

The residues R can all be of the same design or different residues R are present. Preferably, the residues R are organic residues, in particular alkyl groups and/or aryl groups. For example, the residues R are formed by methyl groups and/or by phenyl groups.

In FIG. 18, an example of a section of a coating 3 is shown. In order to produce coatings 3 that are almost opaque and preferably have a high reflectivity for visible light, the coating 3 has the polysiloxane with the high proportion of T units as the base material 31, for example as illustrated in FIG. 17. Particles 32 are embedded in the base material 31. The particles 32 are preferably metal oxide particles such as titanium dioxide particles, which act as a scattering center for electromagnetic radiation in the wavelength range in particular from 380 nm to 1500 nm, preferably 430 nm to 780 nm.

Preferably, the particles 32 are present individually in the base material 31. Alternatively, it is possible for a small proportion of the particles 32 to be agglomerated such that a plurality of the particles 32 are directly adjacent to each other. In order to achieve high reflectivity, a weight fraction and/or a volume fraction of the particles 32 is preferably set comparatively high, whereby significant agglomeration of particles is preferably avoided.

The components shown in the figures preferably follow one another in the sequence indicated, in particular immediately one after the other, unless otherwise described. Layers that do not touch in the figures are preferably spaced apart. Insofar as lines are drawn parallel to one another, the associated surfaces are preferably likewise aligned parallel to one another. Furthermore, the relative positions of the drawn components to each other are correctly reproduced in the figures, unless otherwise described.

The invention described herein is not limited by the description based on the exemplary embodiments. Rather, the invention encompasses any new feature as well as any combination of features, which in particular includes any combination of features in the patent claims, even if this feature or combination itself is not explicitly stated in the patent claims or exemplary embodiments.

1.-16. (canceled)

17. An optical component comprising:
an optical body at least partially translucent to visible light; and
a coating directly arranged at the optical body,
wherein the coating has a reflection coefficient of at least 0.8 for at least one wavelength range in a range from 380 nm to 1500 nm and an average thickness between 10 μm and 200 μm inclusive,
wherein the coating has a polysiloxane as base material, and
wherein the polysiloxane comprises —SiO_{3/2} units.

18. An optoelectronic semiconductor component comprising:
at least one optical component according to claim 17; and
at least one radiation-emitting optoelectronic semiconductor chip, the at least one optoelectronic chip configured to emit radiation,
wherein the at least one optical component is attached to the at least one optoelectronic semiconductor chip, and
wherein the optical component is configured to emit the radiation out of the semiconductor component at least partially through the optical component.

19. A method for producing an optical component, the method comprising:
providing a plurality of optical bodies at least partially translucent to visible light;
applying a liquid coating material directly to the optical bodies;
solidifying the coating material to form a coating; and
separating through the coating the optical components,
wherein the finished coating has an average thickness between 10 μm and 200 μm inclusive,
wherein the finished coating comprises a polysiloxane as base material,
wherein the polysiloxane comprises —SiO_{3/2} units, and
wherein the method is performed in the order indicated.

20. The method according to claim 19, further comprising:
applying a temporary mask to top faces of the optical bodies after providing the plurality of optical bodies and before applying the liquid coating material;
wherein providing the plurality of optical bodies comprises applying rear sides of the optical bodies to a carrier, the top faces being opposite the rear sides;
removing the mask after applying the liquid coating material; and
completely removing the carrier after forming the coating.

21. The method according to claim 20, wherein the optical bodies taper in a direction towards the top face.

22. The method according to claim 19, wherein only side surfaces of the optical bodies are provided with the coating material and thus with the coating.

23. The method according to claim 19, wherein the finished coating exhibits a transmission coefficient for visible light of at most 0.05 and a reflection coefficient of at least 0.8.

24. The method according to claim 19, wherein the coating material and the coating comprise scattering particles embedded in the base material, wherein the scattering particles have a larger refractive index than the base material, wherein an average diameter of the scattering particles is between 0.15 μm and 0.5 μm, inclusive, and wherein a weight fraction and/or a volume fraction of the scattering particles in the coating material is between 40% and 70%, inclusive.

25. The method according to claim 19, wherein the optical body is a luminescent body configured to partially or completely convert a short wavelength radiation incident on or passing through the optical body into a longer wavelength radiation.

26. The method according to claim 25, wherein the optical body comprises or is a ceramic body and the ceramic body includes at least one phosphor, and wherein the at least one phosphor is configured to generate green, yellow, orange and/or red light from blue light and/or from ultraviolet radiation.

27. The method according to claim 19, further comprising:
attaching radiation-emitting optoelectronic semiconductor chips on the coated optical bodies after forming the coating.

28. The method according to claim 19, further comprising:
producing a cladding on the coating after forming the coating, wherein the finished cladding has an average layer thickness greater by at least a factor of three than the finished coating, and wherein the cladding comprises a further polysiloxane as a further base material.

29. The method according to claim 19, wherein an average lateral extent of the optical bodies, as seen in plan view, is between 0.2 mm and 2 mm, inclusive, wherein an average thickness of the optical bodies is between 30 μm and 2 mm, inclusive, and wherein the finished coating is thinner than the optical bodies.

30. The method according to claim 19, wherein, taken together, at least 80% of base units of the polysiloxane of the finished coating are formed by —SiO_{3/2} units and by —SiO_{4/2} units, and wherein a proportion of the —SiO_{3/2} units exceeds a proportion of the —SiO_{4/2} units.

31. The method according to claim 30, wherein at least 70% of the base units of the polysiloxane of the finished coating are —SiO_{3/2} units, and wherein organic residues on the —SiO_{3/2} units are predominantly formed by phenyl groups and/or by methyl groups.

32. The method according to claim 19, wherein, while forming the coating, a loss in mass of the coating material, in terms of a hydrolyzable volatile organic content, is between 10% and 35%, inclusive, and wherein the solidifying includes a final curing at a temperature between 150° C. and 250° C., inclusive, for a duration of between 2 h and 24 h, inclusive.
